(19) United States
(12) Patent Application Publication
(10) Pub. No.: US 2018/0301269 A1
(43) Pub. Date: Oct. 18, 2018

(54) INDUCTOR WITH INTEGRATED HEAT DISSIPATION STRUCTURES

(71) Applicant: Intel Corporation, Santa Clara, CA (US)

(72) Inventor: Arvind SUNDARAM, Bangalore (IN)

(21) Appl. No.: 15/486,167

(22) Filed: Apr. 12, 2017

(51) Int. Cl. H01F 27/22; H01F 27/28; H01F 27/29; H01F 27/24; H01L 23/64; H01L 23/367; H01L 23/373

(52) U.S. Cl. CPC H01F 27/22; H01F 27/28; H01F 27/29; H01L 2223/6661; H01L 23/645; H01L 23/3672; H01L 23/373; H01F 27/24

(57) ABSTRACT

Techniques and mechanisms for providing an inductor with integrated heat dissipation structures. In an embodiment, the inductor includes an electrical conductor and a ferromagnetic body, wherein a portion of the conductor extends through the ferromagnetic body. The conductor further includes other portions which extend from the ferromagnetic body, wherein the other portions each further form or couple to respective fin structures. In another embodiment, the inductor includes multiple distinct ferromagnetic bodies, where different portions of the conductor variously extend each through a respective one of the ferromagnetic bodies.

### BACKGROUND

### 1. Technical Field

Embodiments of the present invention generally relate to circuit structures and more particularly, but not exclusively, to heat dissipation structures of an inductor device.

### 2. Background Art

Efficient and effective integrated circuit device heat dissipation during operation is increasingly important as integrated circuit (IC) device power consumption continues to rise. This is particularly true for highly integrated IC chips and packaged devices, for example. Ineffective heat dissipation may lead to reliability issues and shorten the useful life of an IC device.

To prevent such issues, many different types of heat dissipation approaches have been used. For example, system fans, heat pipes and heat sinks coupled to device packages are often provided in an effort to dissipate heat generated by integrated circuitry and other electronic devices as quickly as possible. The approach used to dissipate heat for a particular device may depend on the type of package in which the device is provided, the manner in which the device is connected to a system board, and/or the system in which the device will be operating.

As successive generations of IC technologies continue to scale in size and increased functionality, there is expected to be an increased premium placed on incremental improvements to heat dissipation structures and techniques.

### BRIEF DESCRIPTION OF THE DRAWINGS

The various embodiments of the present invention are illustrated by way of example, and not by way of limitation, in the figures of the accompanying drawings and in which:

FIG. 1 shows perspective views illustrating elements of an inductor device according to an embodiment.

FIG. 2 is a flow diagram illustrating elements of a method to provide an inductor according to an embodiment.

FIGS. 3A-3C show perspective views each showing structures during a corresponding stage of processing to fabricate an inductor device according to an embodiment.

FIGS. 4A, 4B show respective inductance devices each according to a corresponding embodiment.

FIG. 5 is a functional block diagram illustrating elements of a computer device according to an embodiment.

FIG. 6 is a functional block diagram illustrating elements of a computer system according to an embodiment.

### DETAILED DESCRIPTION

Embodiments discussed herein variously include techniques and/or mechanisms for providing functionality of an inductor device which includes integrated heat dissipation structures. In an embodiment, an inductor includes an electrical conductor and a body comprising a ferromagnetic material (referred to herein as a “ferromagnetic body”), wherein a portion of the conductor extends through the ferromagnetic body. Other portions of the conductor may variously extend from the ferromagnetic body, wherein the other portions each form one or more respective fin structures to facilitate a dissipation of heat. Some or all such heat may be generated, for example, by the inductor and/or by circuitry which is coupled to the inductor. In some embodiments, the inductor includes multiple distinct ferromagnetic bodies, where different portions of the conductor variously extend each through a respective one of the ferromagnetic bodies.

As used herein, “fin structure” refers to any of the variety of branch portions formed by a conductor—e.g., wherein such a branch portion generally extends at a perpendicular angle (or at an oblique angle) from some other portion of the conductor. A bend, curve, junction or other such structure of the conductor may be an interface between a fin structure thereof and the other region of the conductor. A fin structure may extend to form a distal end of a conductor—e.g., wherein any physical coupling of the inductor to some external structure is only via a connection other than any at the fin structure.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including an inductor comprising integrated heat dissipation structures, as described herein.

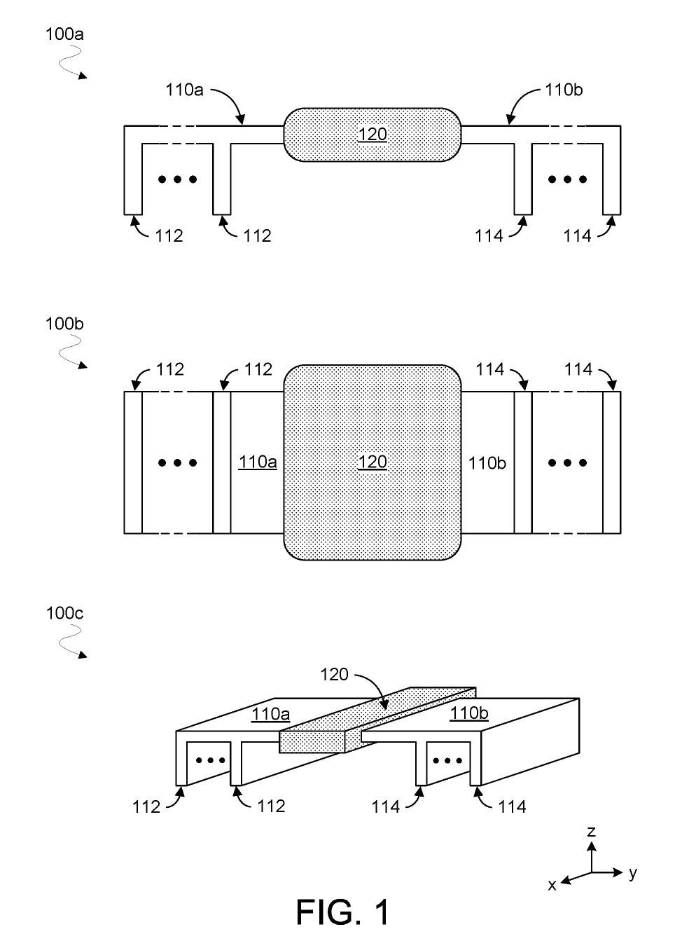

FIG. 1 shows a side view 100a, top view 100b and perspective view 100c each of an inductor device, according to an embodiment, which includes structures to facilitate heat dissipation. The inductor device of FIG. 1 is one example of an embodiment wherein a conductor extends through a structure (referred to herein as an “ferromagnetic body”) to facilitate signal inductance characteristics, and further extends to form fin structures with which heat may be dissipated.

In the illustrative embodiment shown, the inductor device of FIG. 1 includes a ferromagnetic body 120 and a conductor extending therethrough—e.g., wherein the conductor includes conductive portions 110a, 100b each extending from a respective side of ferromagnetic body 120. Another portion (not shown) of the conductor may couple portions 110a, 100b to one another, wherein ferromagnetic body 120 extends around that other portion. Such a portion of a conductor is referred to herein as a “median conductor portion.”

Portions 110a, 110b may variously extend each from a respective sire of ferromagnetic body 120, wherein heat dissipation structures (or “fin structures”) are variously formed by, or extend each from, a respective one of portions 110a, 110b. In the illustrative embodiment shown, one or more fin structures (such as the illustrative fin structures 112 shown) extend from a generally planar structure of conductive portion 110a. Alternatively or in addition, one or more other fin structures (such as the illustrative fin structures 114 shown) may extend from a generally planar structure of conductive portion 110b. Although some embodiments are not limited in this regard, one or more sides of conductive portions 110a, 100b and/or of the median conductor portion may extend in a plane from which extend some or all of fin structures 312, 314.

The inductor variously shown in views 100a, 100b, 100c may facilitate coupling to source circuitry and sink circuitry (not shown) which are to communicate a signal via the inductor. For example, portions 110a, 110b may each form, or couple to, a respective terminal (i.e., a conductive pin, pad, ball, pad, or other such contact structure) by which external circuitry is to couple to the inductor. Some embodiments are not limited with respect to a particular configuration and/or functionality of circuitry that might communicate a signal with an inductor device such as that shown in FIG. 1. One or both such terminals (or other structure of the inductor) may function as a path by which heat is conducted to and/or in the conductor—e.g., where such heat is dissipated at least in part with fin structures 312, 314.

In an embodiment, the conductor—e.g., including copper (e.g., plated with silver or gold), aluminum and/or any of a variety of other metals or alloys thereof—is stamped, molded or otherwise shaped into the form shown. Ferromagnetic body 120 may comprise any of a variety of one or more materials—e.g., including, but not limited to, nickel zinc (NiZn), magnesium zinc (MgZn), a ferrite, perovskite, zirconate, titanate or cobalt based magnetic material or the like—which exhibit low core loss, low hysteresis and/or high flux capability (e.g., at frequencies in a range of 5 Mhz to 50 Mhz). Formation of ferromagnetic body 120 around the conductor may include sintering or otherwise transforming the one or more materials—e.g., from a powder or other granular state into a single rigid body. Fabrication of the inductor may use one or more materials and/or operations adapted, for example, from conventional techniques for manufacturing circuit elements. The particular details of such conventional techniques are not detailed herein to avoid obscuring certain features of various embodiments.

In one example embodiment, an overall width (x-axis) of the conductor may be in a range of 8 millimeters (mm) to 12 mm—e.g., wherein an overall length (y-axis) of the conductor is also in a range of 8 mm to 12 mm. In such an embodiment, a z-axis thickness of the median conductor portion (which extends through ferromagnetic body 120) may, for example, be in a range of 0.05 mm to 0.1 mm (e.g., in a range of 0.1 mm to 0.2 mm). Some or all of fin structures 112, 114 may each have a respective z-axis height which is in a range of 1.0 mm to 2.5 mm—e.g., wherein such fin structures each have a respective y-axis thickness in a range of 0.05 mm to 0.1 mm. Alternatively or in addition, a thickness (z-axis) of ferromagnetic body 120 on one side of the median conductor portion may, for example, be in a range of 0.5 mm to 1.0 mm—e.g., where an overall thickness of ferromagnetic body 120 is in a range of 1.5 mm to 3.0 mm. In such an embodiment, ferromagnetic body 120 may, for example, have a width (x-axis) in a range of 6 mm to 12 mm and/or a length (y-axis) in a range of 4 mm to 10 mm. However, such dimensions of the conductor and fin structures 312, 314 are merely illustrative, and may vary in other embodiments according to implementation specific details.

The inductor may include more, fewer and/or differently configured fin structures, in other embodiments. For example, in the illustrative embodiment represented by FIG. 1, fin structures 312, 314 all extend in a same direction from the same side of a generally planar structure formed in part by portions 110a, 110b. Moreover, as shown, fin structures 312, 314 also extend each at a right angle from such a side of the planar structure. However, some embodiment may vary, for example, with respect to the total number of one or more fin structures on any given side of ferromagnetic body 120, the respective side or sides of the conductor from which some or all such fin structures variously extend, the respective angles at which some or all fin structures may variously extend and/or the like.

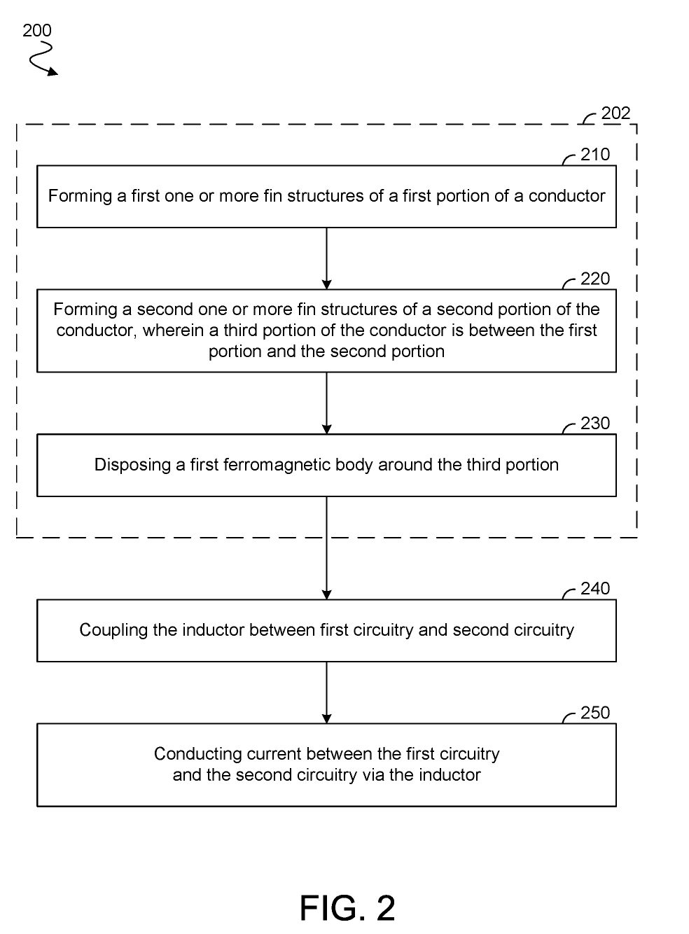

FIG. 2 shows features of a method 200 to provide circuit inductance according to an embodiment. Method 200 may be performed to fabricate or otherwise provide functionality of the inductor shown in views 100a, 100b, 100c, for example.

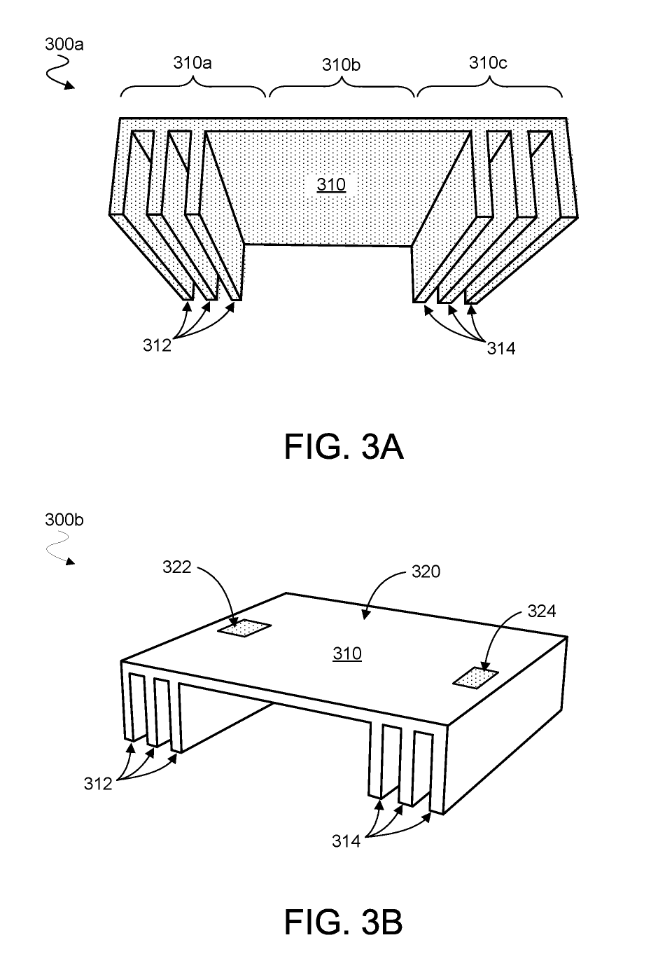

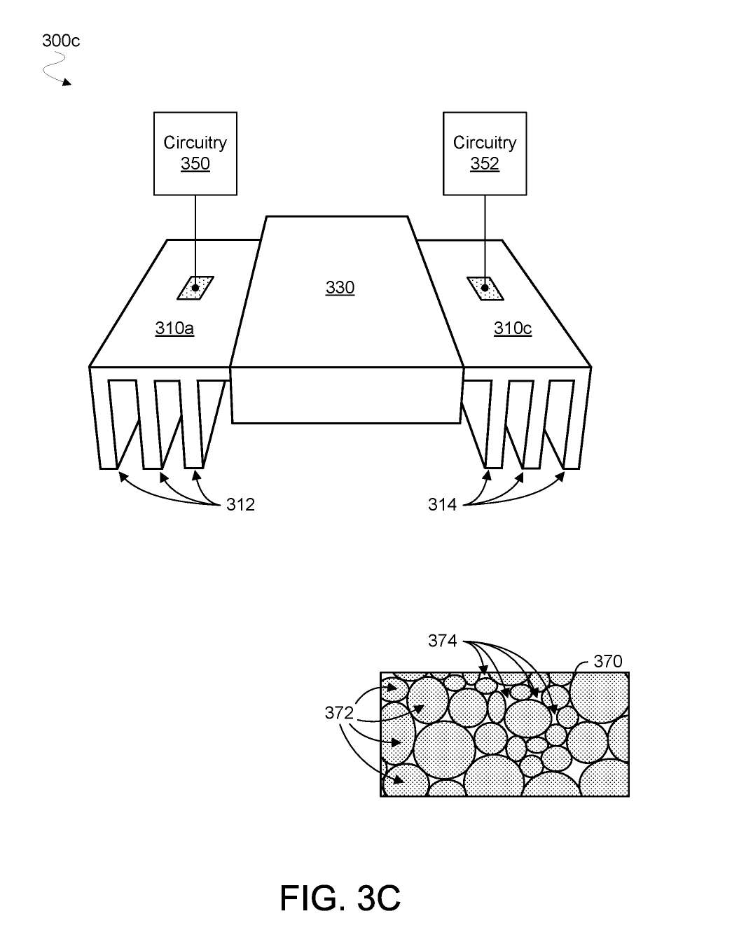

FIGS. 3A-3C show respective stages 300a-300c of processing to fabricate, according to an embodiment, an inductor which, for example, has features shown in FIG. 1. To illustrate certain features of various embodiments, method 200 is described herein with respect to processing to fabricate structures such as those shown in stages 300a-300c. However, such description may be extended to apply to processing which fabricates any of a variety of additional or alternative inductor structures having features described herein.

Method 200 may include operations 202, such as that shown in stages 300a-300c, to fabricate an inductor. In an embodiment, operations 202 include, at 210, forming a first one or more fin structures (e.g., fin structures 312) of a first portion of the conductor. Operations 202 may further comprise, at 220, forming a second one or more fin structures of a second portion of the conductor, wherein a third portion of the conductor is between the first portion and the second portion

Referring now to FIG. 3A, a conductive body 310 at stage 300a includes portions 310a, 310c and another portion 310b therebetween. In the illustrative embodiment shown, portions 310a, 310b, 310c variously extend to form, at least in part, a substantially planar structure. In such an embodiment, conductor 310 may further form heat dissipation structures which variously extend from such a planar structure. By way of illustration and not limitation, portion 310a may form or couple to first fins 312 which extend (for example) from a plane—e.g., where some or all of portions 310a, 310b, 310c include side structures which extend in the plane. Alternatively or in addition, portion 310c may include or couple to second fins 314 which (for example) also extend from such a plane. In the example embodiment illustrated with stage 300a, fins 312 and fins 314 variously extend in parallel with to one another each in a direction which is substantially perpendicular to a plane formed by side structures of portions 310a, 310b, 310c. However, the number, size, direction and/or other configuration of fins 312 and/or of fins 314 may vary in different embodiments.

During or after the processing of operations 202, the first portion and the second portion may each include or couple to a respective terminal by which the inductor is to couple to other circuitry. For example, as shown at stage 300b in FIG. 3B, a coating 320 may be selectively patterned to leave exposed respective surface regions 322, 324 of portions 310a, 310b—e.g., wherein surface regions 322, 324 (or respective contact structures formed on surface regions 322, 324) are later to serve as terminals for coupling the finally formed inductor device to other circuit structures. Coating 320 may comprise any of a variety of passivation, insulation, anti-corrosive and/or other materials such as those adapted from conventional circuit fabrication processes.

In an embodiment, operations 202 further includes, at 230, disposing a first ferromagnetic body around the third portion. For example, as shown in stage 300c of FIG. 3C, a ferromagnetic body 330 including a ferromagnetic material may be injection molded, sintered, bonded and/or otherwise formed around the median portion 310b between portions 310a, 310c.

Physical properties of the ferromagnetic material may facilitate inductance to provide high frequency signaling. For example, as illustrated by the cross-sectional detail view in inset 370 of FIG. 3C, ferromagnetic body 330 may include particles, granules and/or other such clusters of ferromagnetic material that variously extend around gap regions in ferromagnetic body 330. Such clusters (referred to herein as “ferromagnetic node structures”) may be variously melted or otherwise bonded to one another—e.g., by a sintering process. For example, these nodes may include distinct ferromagnetic particles which variously adjoin one another and/or may include ferromagnetic structures which are melted together at their respective surfaces. An interface between one ferromagnetic node structure and an adjoining ferromagnetic node structure may be indicated, for example, by a local minimum in the cross-sectional area of any ferromagnetic material between the node structures.

In the illustrative embodiment shown by inset 370, ferromagnetic body 330 comprises ferromagnetic node structures 372 which variously adjoin and extend around gap regions 374. Gap regions 374 may variously have disposed therein air and/or a binding material used to facilitate a sintering or other process to bond ferromagnetic particles. Such a binding material may include paraffin, for example, although some embodiments are not limited in this regard. The respective lengths (e.g., diameters) of ferromagnetic node structures 372 may, for example, be in a range of 30 nanometers (nm) to 30 microns—e.g., depending on implementation specific details.

Ferromagnetic body 330 may have at least some minimum volume fraction which is attributable to gap regions such as the illustrative gap regions 374 shown. In providing such a minimum volume fraction of gap regions (and a corresponding maximum volume fraction of all ferromagnetic material of the layer), some embodiments mitigate the possibility of the inductor being saturated during its operation. By way of illustration and not limitation, a volume fraction of ferromagnetic material in ferromagnetic body 330 may be equal to or less than 97%—e.g., wherein the volume fraction of gap regions 374 in ferromagnetic body 330 is in a range of 3% to 25% (and, in some embodiments, in a range of 5% to 15%). It is understood that the total volume of ferromagnetic body 330 does not include the volume of other structures which are surrounded by ferromagnetic body 330—e.g., where such structures include portion 310b.

The volume fraction of gap regions 374 may be due at least in part to ferromagnetic node structures 372 comprising node structures of different sizes—e.g., wherein the respective sizes (for example, lengths) of ferromagnetic node structures 372 have a non-Gaussian distribution. By way of illustration and not limitation, ferromagnetic node structures 372 may consist of a combination of first ferromagnetic node structures having a first Gaussian size distribution and second ferromagnetic node structures having a second Gaussian size distribution. In such an embodiment, a difference—e.g., an absolute difference—between a first average of the first Gaussian size distribution and a second average of the second Gaussian size distribution may be at least 10% (in some embodiments, at least 20%) of the second average. Any of a variety of other combinations of two or more different sizes of ferromagnetic node structures may be implemented, in various embodiments.

In some embodiments, method 200 may additionally or alternatively include coupling an inductor (such as that formed by operations 202) to other circuitry—e.g., including source circuitry which is to provide current to the inductor and/or to sink circuitry which is to receive current from the inductor. For example, method 200 may include, at 240, coupling the inductor between first circuitry and second circuitry. Referring again to FIG. 3C, the coupling at 240 may include coupling circuitry 350 to conductor 310 via surface region 322—e.g., wherein other circuitry 352 is further coupled to conductor 310 via surface region 324. Circuitry 350 and circuitry 352 may, for example, be different respective portions of a single circuit which is to send a current through the inductor. Some embodiments are not limited to particular circuit structure of circuitry 350 and/or circuitry 352.

In the example embodiment shown, surface regions 322, 324 are disposed on a first side of conductor 310, wherein fins 312, 314 variously extend from a second side of conductor 310 (the second side opposite the first side). However, some embodiments are not limited with respect to the location of terminals relative to fin structures. In an alternative embodiment, one or both terminals may instead be variously disposed on the first side of the conductor—e.g., where a terminal is located in a region between ferromagnetic body 330 and fin structures 312 (or in a region between ferromagnetic body 330 and fin structures 314).

Alternatively or in addition, method 200 may include operating circuitry including an inductor (such as that formed by operations 202)—e.g., where such circuitry is interconnected at 240. For example, method 200 may include, at 250, conducting current between the first circuitry and the second circuitry (in an embodiment, between circuitry 350 and circuitry 352) via the inductor.

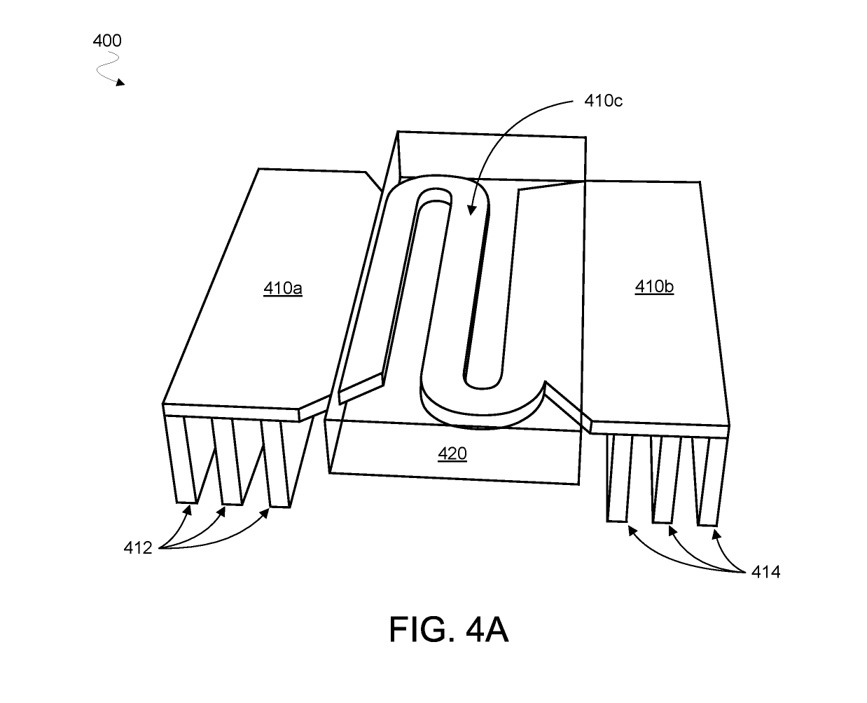

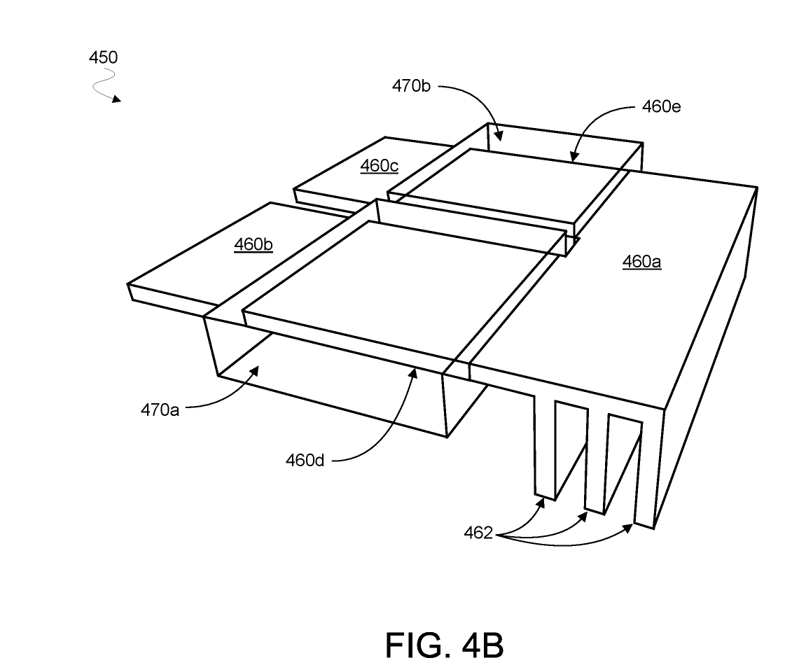

FIG. 4A shows features of an inductor device 400 which has integrated heat dissipation structures according to another embodiment. Inductor 400 may include features such as those shown in one of FIGS. 1, 3C—e.g., wherein structures of inductor device 400 are formed by operations 202. Inductor device 400 is one example of an embodiment wherein a median conductor portion (e.g., portion 310b), disposed in a ferromagnetic body, forms one or more curved and/or angled structures. Such a median conductor portion may include a sidewall structure which forms one or more bends or corners—e.g., wherein the median portion includes one or more serpentine or otherwise corrugated structures.

In the illustrative embodiment shown, inductor 400 includes a conductor comprising portions 410a, 410b and a median portion 410c disposed therebetween. Inductor 400 may further comprise a ferromagnetic body 420 which is molded, sintered, adhered and/or otherwise formed around portion 410c. Ferromagnetic body 420 is shown as being transparent in FIG. 4 merely to illustrate feature of various structures of median portion 410c therein. In an embodiment, median portion 410c forms one or more serpentine structures (such as the illustrative “S” curve shown) to increase inductive interaction between ferromagnetic body 420 and a signal which is to be conducted with median portion 410c. Portions 410a, 410b may include or adjoin respective fin structures 412, 414, for example.

FIG. 4B shows a section of another inductor device 450 which has integrated heat dissipation structures according to a different embodiment. Inductor 450 may include features such as those shown in one of FIGS. 1, 3C, for example—e.g., wherein structures of inductor device 450 are formed by operations 202. Inductor device 450 is one example of another embodiment wherein a conductor (in addition to forming heat dissipation structures) forms multiple median portions each extending through a different respective ferromagnetic body. Such a configuration of a conductor relative to multiple ferromagnetic bodies may facilitate functionality of an in-parallel arrangement of multiple inductors.

In the illustrative embodiment shown, inductor 450 includes a conductor comprising portions 460a, 460b, 460c. The conductor may further comprise a median portion 460d between portions 460a, 460b and another median portion 460e between portions 460a, 460c. Median portions 460d, 460e may facilitate operation of inductor device 450 as an in-parallel combination of two (or more) inductors. For example, inductor 450 may further comprise a ferromagnetic bodies 470a, 470b which are variously molded, sintered, adhered and/or otherwise formed around median portions 460d, 460e, respectively. Ferromagnetic bodies 470a, 470b are each shown as being transparent in FIG. 4 merely to illustrate respective feature of median portions 460d, 460e. Similar to portion 410c, one or both of median portions 460d, 460e may each form one or more angles or curves (not shown), although some embodiments are not limited in this regard. Portion 460a may include or adjoin fin structures 462, for example.

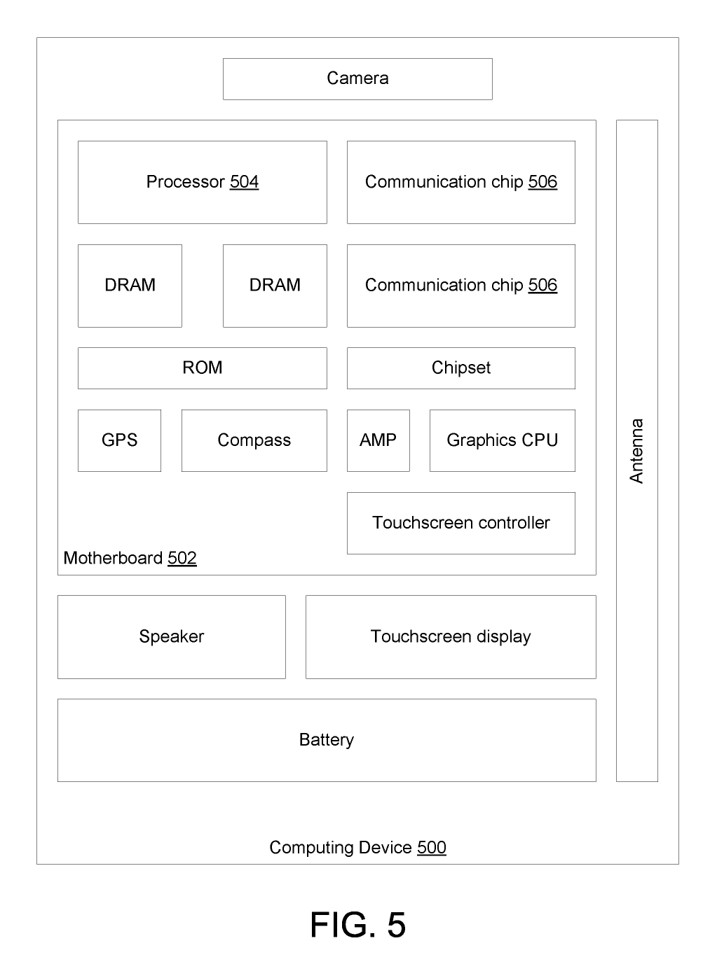

FIG. 5 illustrates a computing device 500 in accordance with one embodiment. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. The term “processor” may refer to any device or portion of a device that processes electronic data from registers and/or memory to transform that electronic data into other electronic data that may be stored in registers and/or memory. The communication chip 506 also includes an integrated circuit die packaged within the communication chip 506. In an embodiment, the motherboard 502 includes or couples to an inductor (not shown) as described herein.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

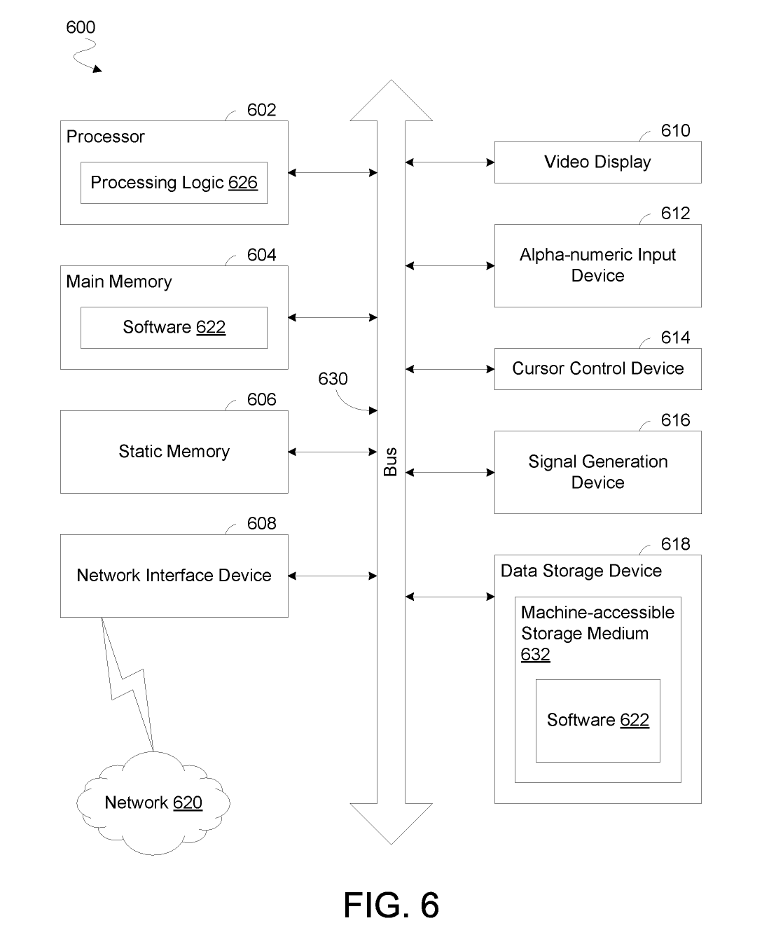

FIG. 6 illustrates a diagrammatic representation of a machine in the exemplary form of a computer system 600 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker). In an embodiment, computer system 600 includes or couples to an inductor (not shown) as described herein.

The secondary memory 618 may include a machine-accessible storage medium (or more specifically a computer-readable storage medium) 632 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, an inductor comprises a conductor including a first portion which forms a first one or more fin structures, wherein the first portion includes or couples to a first terminal by which the inductor is to couple to first circuitry, a second portion which forms a second one or more fin structures, wherein the second portion includes or couples to a second terminal by which the inductor is to couple to second circuitry, and a third portion disposed between the first portion and the second portion. The inductor further comprises a first ferromagnetic body disposed around the third portion.

In one embodiment, a volume fraction of ferromagnetic material of the first ferromagnetic body is equal to or less than ninety seven percent (97%). In another embodiment, the first one or more fin structures includes a first plurality of fin structures, and wherein the second one or more fin structures includes a second plurality of fin structures. In another embodiment, the first one or more fin structures extend from a first side of a sub-portion of the first portion, wherein the first terminal is disposed on a second side of the sub-portion, the second side opposite the first side. In another embodiment, the first one or more fin structures extend from a first side of a sub-portion of the first portion, wherein the first terminal is disposed on the first side of the sub-portion in a region between the first ferromagnetic body and the first one or more fin structures. In another embodiment, the third portion forms a first sidewall structure in the first ferromagnetic body, wherein the first sidewall structure forms a bend or corner. In another embodiment, a size distribution for ferrite node structures of the first ferromagnetic body is other than any Gaussian distribution. In another embodiment, the conductor further comprises a fourth portion disposed between the first portion and the second portion, the inductor further comprising a second ferromagnetic body disposed around the fourth portion. In another embodiment, the third portion forms a first sidewall structure in the first ferromagnetic body, wherein the fourth portion forms a second sidewall structure in the first ferromagnetic body, wherein the first sidewall structure and the second sidewall structure each form a respective bend or corner.

In another implementation, a method comprises fabricating an inductor, including forming a conductor including forming a first one or more fin structures of a first portion of the conductor, wherein the first portion includes or couples to a first terminal, and forming a second one or more fin structures of a second portion of the conductor, wherein the second portion includes or couples to a second terminal, wherein a third portion of the conductor is between the first portion and the second portion. Fabricating the inductor further comprises disposing a first ferromagnetic body around the third portion.

In one embodiment, a volume fraction of ferromagnetic material of the first ferromagnetic body is equal to or less than ninety seven percent (97%). In another embodiment, the first one or more fin structures includes a first plurality of fin structures, and wherein the second one or more fin structures includes a second plurality of fin structures. In another embodiment, the first one or more fin structures extend from a first side of a sub-portion of the first portion, wherein the first terminal is disposed on a second side of the sub-portion, the second side opposite the first side. In another embodiment, the first one or more fin structures extend from a first side of a sub-portion of the first portion, wherein the first terminal is disposed on the first side of the sub-portion in a region between the first ferromagnetic body and the first one or more fin structures. In another embodiment, the third portion forms a first sidewall structure in the first ferromagnetic body, wherein the first sidewall structure forms a bend or corner. In another embodiment, a size distribution for ferrite node structures of the first ferromagnetic body is other than any Gaussian distribution. In another embodiment, the conductor further comprises a fourth portion disposed between the first portion and the second portion, the inductor further comprising a second ferromagnetic body disposed around the fourth portion. In another embodiment, the third portion forms a first sidewall structure in the first ferromagnetic body, wherein the fourth portion forms a second sidewall structure in the first ferromagnetic body, wherein the first sidewall structure and the second sidewall structure each form a respective bend or corner. In another embodiment, the method further comprises coupling the inductor to first circuitry via the first terminal and to second circuitry via the second terminal. In another embodiment, the method further comprises communicating a signal between the first circuitry and the second circuitry via the inductor.

In another implementation, a system comprises an inductor including a conductor comprising a first portion which forms a first one or more fin structures, wherein the first portion includes or couples to a first terminal, a second portion which forms a second one or more fin structures, wherein the second portion includes or couples to a second terminal, and a third portion disposed between the first portion and the second portion. The inductor further comprises a first ferromagnetic body disposed around the third portion. The system further comprises first circuitry coupled to the inductor via the first terminal, second circuitry coupled to the inductor via the second terminal, wherein the conductor to communicate a signal between the first circuitry and the second circuitry, and a display device coupled to one of the first circuitry and the second circuitry, the display device to display an image based on the signal.

In one embodiment, a volume fraction of ferromagnetic material of the first ferromagnetic body is equal to or less than ninety seven percent (97%). In another embodiment, the first one or more fin structures includes a first plurality of fin structures, and wherein the second one or more fin structures includes a second plurality of fin structures. In another embodiment, the first one or more fin structures extend from a first side of a sub-portion of the first portion, wherein the first terminal is disposed on a second side of the sub-portion, the second side opposite the first side. In another embodiment, the first one or more fin structures extend from a first side of a sub-portion of the first portion, wherein the first terminal is disposed on the first side of the sub-portion in a region between the first ferromagnetic body and the first one or more fin structures. In another embodiment, the third portion forms a first sidewall structure in the first ferromagnetic body, wherein the first sidewall structure forms a bend or corner. In another embodiment, a size distribution for ferrite node structures of the first ferromagnetic body is other than any Gaussian distribution. In another embodiment, the conductor further comprises a fourth portion disposed between the first portion and the second portion, the inductor further comprising a second ferromagnetic body disposed around the fourth portion. In another embodiment, the third portion forms a first sidewall structure in the first ferromagnetic body, wherein the fourth portion forms a second sidewall structure in the first ferromagnetic body, wherein the first sidewall structure and the second sidewall structure each form a respective bend or corner.

Techniques and architectures for providing heat dissipation with circuit structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An inductor comprising:
a conductor including:
a first portion which forms a first one or more fin structures, wherein the first portion includes or couples to a first terminal by which the inductor is to couple to first circuitry;
a second portion which forms a second one or more fin structures, wherein the second portion includes or couples to a second terminal by which the inductor is to couple to second circuitry; and
a third portion disposed between the first portion and the second portion; and
a first ferromagnetic body disposed around the third portion.

2. The inductor of claim 1, wherein a volume fraction of ferromagnetic material of the first ferromagnetic body is equal to or less than ninety seven percent (97%).

3. The inductor of claim 1, wherein the first one or more fin structures includes a first plurality of fin structures, and wherein the second one or more fin structures includes a second plurality of fin structures.

4. The inductor of claim 1, wherein the first one or more fin structures extend from a first side of a sub-portion of the first portion, wherein the first terminal is disposed on a second side of the sub-portion, the second side opposite the first side.

5. The inductor of claim 1, wherein the first one or more fin structures extend from a first side of a sub-portion of the first portion, wherein the first terminal is disposed on the first side of the sub-portion in a region between the first ferromagnetic body and the first one or more fin structures.

6. The inductor of claim 1, wherein the third portion forms a first sidewall structure in the first ferromagnetic body, wherein the first sidewall structure forms a bend or corner.

7. The inductor of claim 1, wherein a size distribution for ferrite node structures of the first ferromagnetic body is other than any Gaussian distribution.

8. The inductor of claim 1, wherein the conductor further comprises a fourth portion disposed between the first portion and the second portion, the inductor further comprising a second ferromagnetic body disposed around the fourth portion.

9. The inductor of claim 8, wherein the third portion forms a first sidewall structure in the first ferromagnetic body, wherein the fourth portion forms a second sidewall structure in the first ferromagnetic body, wherein the first sidewall structure and the second sidewall structure each form a respective bend or corner.

10. A method comprising
fabricating an inductor, including:
forming a conductor including:
forming a first one or more fin structures of a first portion of the conductor, wherein the first portion includes or couples to a first terminal;
forming a second one or more fin structures of a second portion of the conductor, wherein the second portion includes or couples to a second terminal, wherein a third portion of the conductor is between the first portion and the second portion; and
disposing a first ferromagnetic body around the third portion.

11. The method of claim 10, wherein a volume fraction of ferromagnetic material of the first ferromagnetic body is equal to or less than ninety seven percent (97%).

12. The method of claim 10, wherein the first one or more fin structures extend from a first side of a sub-portion of the first portion, wherein the first terminal is disposed on the first side of the sub-portion in a region between the first ferromagnetic body and the first one or more fin structures.

13. The method of claim 10, wherein the third portion forms a first sidewall structure in the first ferromagnetic body, wherein the first sidewall structure forms a bend or corner.

14. The method of claim 10, wherein the conductor further comprises a fourth portion disposed between the first portion and the second portion, the inductor further comprising a second ferromagnetic body disposed around the fourth portion.

15. The method of claim 10, further comprising coupling the inductor to first circuitry via the first terminal and to second circuitry via the second terminal.

16. The method of claim 15, further comprising communicating a signal between the first circuitry and the second circuitry via the inductor.

17. A system comprising:
an inductor including:
a conductor comprising:
a first portion which forms a first one or more fin structures, wherein the first portion includes or couples to a first terminal;
a second portion which forms a second one or more fin structures, wherein the second portion includes or couples to a second terminal; and
a third portion disposed between the first portion and the second portion; and
a first ferromagnetic body disposed around the third portion;
first circuitry coupled to the inductor via the first terminal;
second circuitry coupled to the inductor via the second terminal, wherein the conductor to communicate a signal between the first circuitry and the second circuitry; and
a display device coupled to one of the first circuitry and the second circuitry, the display device to display an image based on the signal.

18. The system of claim 17, wherein a volume fraction of ferromagnetic material of the first ferromagnetic body is equal to or less than ninety seven percent (97%).

19. The system of claim 17, wherein the third portion forms a first sidewall structure in the first ferromagnetic body, wherein the first sidewall structure forms a bend or corner.

20. The system of claim 17, wherein the conductor further comprises a fourth portion disposed between the first portion and the second portion, the inductor further comprising a second ferromagnetic body disposed around the fourth portion.
